(19) United States
(12) Patent Application Publication
(10) Pub. No.: US 2002/0019092 A1
(43) Pub. Date: Feb. 14, 2002

(54) Method for manufacturing semiconductor device having uniform silicon glass film

(76) Inventors: Koji Arita, Tokyo (JP); Yasuhiro Ono, Tokyo (JP)

Correspondence Address: SCULLY, SCOTT, MURPHY & PRESSER, 400 Garden City Plaza, Garden City, NY, 11530, US

(21) Appl. No.: 09/971,558

(22) Filed: Oct. 5, 2001

Related U.S. Application Data
(63) Continuation of application No. 09/592,171, filed on Jun. 12, 2000.

(30) Foreign Application Priority Data
Jun. 14, 1999 (JP) 11-166602

(51) Int. Cl. H01L 21/8242; H01L 21/20

(52) U.S. Cl. 438/240; 438/253; 438/255; 438/396; 438/398

(57) ABSTRACT

A method for manufacturing a semiconductor device including the steps of: forming a bottom electrode overlying a semiconductor substrate; forming an insulation film on the bottom electrode; subjecting a surface of the insulation film to a plasma treatment; and forming a silicon glass mask on the insulation film. The plasma treatment forms, on the insulation film, a layer for easily receiving an adsorption layer, thereby the film can be formed uniformly.

### BACKGROUND OF THE INVENTION

(a) Field of the Invention

The present invention relates to a method for manufacturing a semiconductor device having a uniform silicon glass film acting as an etching mask.

(b) Description of the Related Art

With higher integration of a semiconductor storage device such as a DRAM (Dynamic Random Access Memory), use of an insulation film having a high dielectric constant such as (Ba,Sr)TiO₃ has been frequently examined as a capacitive insulation film in place of a silicon oxide film and a silicon nitride film. In this case, use of a SiO₂ mask in addition to a PR mask is currently examined for use in etching the insulation film having the high dielectric constant.

FIGS. 1A and 1B show consecutive steps of manufacturing a semiconductor device wherein a silicon glass film employing a TEOS (tetraethylorthosilicate) material is used as SiO₂ mask. At first, as shown in FIG. 1A, a bottom electrode layer 102 made of Ti, TiN and Ru is deposited on a semiconductor substrate 101by sputtering. Then, a (Ba,Sr)TiO₃ film 103 acting as an insulation film having a high dielectric constant is deposited on the bottom electrode layer 102 by a metaloxide chemical vapor deposition (MO-CVD) technique. Thereafter, as shown in FIG. 1B, a silicon glass film 104 using the TEOS material and having a thickness of 3000 Å is formed as an etching mask for the insulation film 103 by employing a CDV technique.

When the silicon glass film is formed by the conventional technique, the film having a non-uniform thickness is formed as shown in FIG. 1B. In accordance with the examination of the present inventors, a surface roughness of 1000 Å or more was generated for a 3000 Å thickness of the silicon glass film. This is probably because the silicon glass film is influenced by crystallizablility and hydration ability of the underlying insulation film 103, and thereby the uniform film formation becomes difficult.

### SUMMARY OF THE INVENTION

In view of the foregoing, an object of the present invention is to provide a method for manufacturing a semiconductor device capable of forming a uniform silicon glass film on an insulation film having a high dielectric constant by providing a higher adsorption ability to the silicon glass film.

The present invention provides a method for manufacturing a semiconductor device comprising the steps of: forming a bottom electrode layer overlying a semiconductor substrate; forming an insulation film overlying the bottom electrode layer; subjecting a surface of the insulation film to a plasma treatment; and forming a silicon glass film on the insulation film.

In accordance with the present invention, the insulation film having a surface for easily receiving an adsorbed layer is formed, thereby developing a silicon glass film having a uniform thickness thereon.

The above and other objects, features and advantages of the present invention will be more apparent from the following description.

### BRIEF DESCRIPTION OF DRAWINGS

FIGS. 1A and 1B are sectional views consecutively showing a conventional process of manufacturing a semiconductor device.

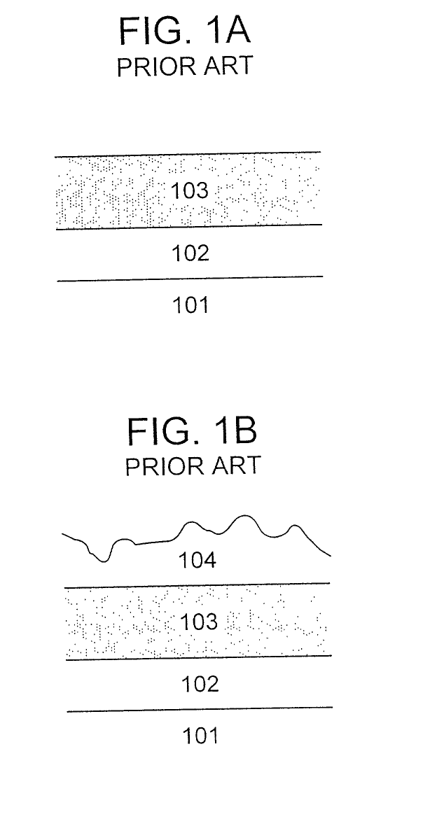

FIGS. 2A to 2C are sectional views consecutively showing a process of manufacturing a semiconductor device in accordance with an embodiment of the present invention.

### PREFERRED EMBODIMENTS OF THE INVENTION

Now, the present invention is more specifically described with reference to accompanying drawings.

First Embodiment

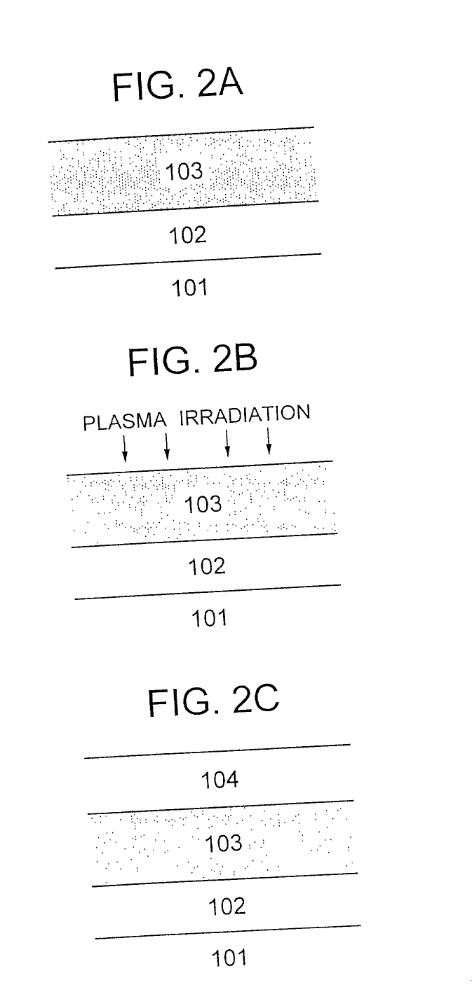

As shown in FIG. 2A, a bottom electrode layer 102 including Ti, TiN and Ru was deposited on a semiconductor substrate 101 by sputtering, and then a (Ba,Sr)TiO₃ film or an insulation film 103 having a high dielectric constant was deposited on the bottom electrode layer 102 by employing a metal-oxide chemical vapor deposition (MO-CVD) process. Thereafter, the surface of the insulation film 103 was treated for 10 seconds in plasma including a mixed gas of Cl₂/Ar (chlorine and argon) at a ratio of 1:1 as shown in FIG. 2B. In the embodiment, another mixed gas other than the Cl₂/Ar can be also employed.

Thereafter, a silicon glass film 104 made of a TEOS material and having a thickness of 3000 Å was formed on the insulation film 103 to provide a semiconductor device of the embodiment.

Further, another semiconductor device was manufactured as a comparative example similarly to that of the embodiment except that the plasma treatment was not conducted.

Surface roughness of the silicon glass of the two semiconductor devices was measured by AFM (atomic force microscope) measurement. The surface roughness of the semiconductor device of the present embodiment was 55 Å whereas that of the comparative example was 1250 Å. The comparative example had an unevenness interval between adjacent convex portions of 300 to 500 nm.

The measurement results showed that the present invention provided an improved uniform thickness for the silicon glass film.

Formation of a top electrode on the insulation film provides a capacitor in the semiconductor device.

Second Embodiment

In a second embodiment, another semiconductor device was manufactured similarly to the first embodiment except that the surface of the insulation film was treated for 5 seconds in the plasma.

Surface roughness of the silicon glass surface of the semiconductor device of the second embodiment was 75 Å as measured by the AFM measurement. This also showed the advantage of the second embodiment over the prior art.

In the embodiment as described above, the layered structure including the respective Ti, TiN and Ru layers was used as the bottom electrode layer. Another bottom electrode layer may be formed by using, in place of the Ru layer, one or more materials including a metal such as Ru, Ir, Re, Os and Rh, an oxide and a silicide thereof, and another material including Pt, Au, Ag, Pd, Ni and Co. Further, at least one of Ti, TiN, TiSix, Ta, TaN, W and WSi may be used in place of the Ti and TiN layers.

In the embodiments, the insulation film having the chemical formula of (Ba,Sr)TiO₃ was used. In the present invention, the insulation film having a representative chemical formula of ABO₃ may be used in which “A” is selected from the group consisting of Ba, Sr, Pb, Ca, La and K, and “B” is selected from the group consisting of Ti, Zr, Ta, Nb, Mg, Fe, Zn and W. Examples of the materials for the insulation film include SrTiO₃, (Sr,Ca)TiO₃, (Ba,Sr,Ca)TiO₃, PbTiO₃, Pb(Zr,Ti)O₃, (Pb,La)(Zr,Ti)O₃, Pb(Mg,Nb)O₃, Pb(Mg,W)O₃, Pb(Zn,Nb)O₃, LiTiO₃, LiNbO₃, KTaO₃ and KNbO₃. The chemical formula of ABO₃ may be replaced with another representative chemical formula of (Bi₂O₂)(Aₘ₋₁BₘO₃ₘ₊₁) in which m=1,2,3,4,5, “A” is selected from the group consisting of Ba, Sr, Pb, Ca, K and Bi and “B” is selected from a group consisting of Nb, Ta, Ti and W. Examples of the materials for the insulation film include Bi₄Ti₃O₁₂, SrBi₂Ta₂O₉ and SrBi₂Nb₂O₉. In case of using Ta₂O₅ different from the above chemical formulae, a similar effect can be also obtained.

In the embodiments, the insulation film of (Ba,Sr)TiO₃ having a two-layered structure was used. As long as the insulation film is present, the silicon glass layer may be multi-layered.

Although the period of the plasma treatment was set to be 5 to 10 seconds in these embodiments, the period is not especially restricted and a similar effect can be obtained regardless of the length of the period. However, the period is preferably shorter in view of reduction of the damage to the insulation film due to the plasma.

Since the above embodiments are described only for examples, the present invention is not limited to the above embodiments and various modifications or alternations can be easily made therefrom by those skilled in the art without departing from the scope of the present invention.

What is claimed is:

1. A method for manufacturing a semiconductor device comprising the steps of:
forming a bottom electrode overlying a semiconductor substrate;
forming an insulation film on the bottom electrode;
subjecting a surface of the insulation film to a plasma treatment; and
forming a silicon glass mask on the insulation film.

2. The method as defined in claim 1, wherein the plasma treatment is conducted by using a mixed gas including chlorine and argon.

3. The method as defined in claim 2, wherein a ratio between the chlorine and the argon is 1:1 in volume.

4. The method as defined in claim 1, wherein a length of period of the plasma treatment is between 5 and 10 seconds.

5. The method as defined in claim 1, wherein the silicon glass film is made of a TEOS material.

6. The method as defined in claim 1 further comprising patterning the insulation film by using the silicon glass mask and forming a top electrode on the patterned insulation film to provide a capacitor.
